(19) United States
(12) Patent Application Publication
(10) Pub. No.: US 2008/0178928 A1
(43) Pub. Date: Jul. 31, 2008

(54) Photovoltaic Modules with a Transparent Material Having a Camouflaged Pattern

(75) Inventors: Donald B. Warfield, Woodbine, MD (US); Paul L. Garvison, Frederick, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 11/961,657

(22) Filed: Dec. 20, 2007

Related U.S. Application Data
(60) Provisional application No. 60/882,609, filed on Dec. 29, 2006.

(51) Int. Cl. H01L 31/048; H01L 31/042; H01L 31/18

(52) U.S. Cl. 136/251; 136/256; 29/592.1

(57) ABSTRACT

A photovoltaic module with a first sheet of a transparent material, an optional second sheet, and at least one photovoltaic cell positioned between the first sheet and the optional second sheet. The transparent material has a camouflaged pattern which can camouflage a photovoltaic module or photovoltaic array on a roofing application. The camouflaged pattern may also include a substantially textured pattern. Also disclosed is a method for making a photovoltaic module comprising sealing at least one photovoltaic cell between a first sheet and a second sheet, wherein the first sheet comprises a camouflaged pattern.

### CROSS REFERENCE TO RELATED APPLICATIONS

This application claims the benefit of U.S. Provisional Patent Application No. 60/882,609 filed on Dec. 29, 2006.

### FIELD OF THE INVENTION

The present invention relates to photovoltaic modules having a first sheet of a transparent material comprising at least one surface, wherein the first sheet comprises a camouflaged pattern on the surface or within the sheet.

### BACKGROUND OF THE INVENTION

Photovoltaic devices convert light energy, particularly solar energy, into electrical energy. Photovoltaically generated electrical energy is a renewable form of electrical energy. One type of photovoltaic device is known as a photovoltaic module, also referred to as a solar module. These modules contain one, or more typically and preferably, a plurality of photovoltaic cells, also referred to as solar cells, positioned and sealed between a first (or upper) sheet, such as a sheet of clear glass or clear polymeric material, and a second sheet, such as a sheet of polymeric material. The sealant, typically referred to as an encapsulant, serves to adhere the first sheet to the second sheet with the photovoltaic cells sealed in the encapsulant between the first and second sheets. Optionally, the first and second sheets may be separated by a nominal distance with the photovoltaic cells places between the sheets, and the sealant would be applied to the edges of the sheets. The photovoltaic cells can be made from wafers of silicon or other suitable semiconductor material, or they can be a thin film-type of cell typically deposited on the first or second sheet by one of the various processes and methods known to those of skill in the art of manufacturing thin film-type photovoltaic cells. One of the more common types of photovoltaic modules contains a plurality of individual photovoltaic cells made from silicon wafers. Such individual photovoltaic cells are typically made of either monocrystalline or multicrystalline silicon wafers and, typically, a number of such individual cells are electrically linked within the module in a desired arrangement to achieve a module having a desired electrical output upon exposure to the sun.

In most applications, photovoltaic modules are mounted in an outside location such as on a rooftop or supporting structure designed to support one or more photovoltaic modules. The aggregation of such photovoltaic modules are known as photovoltaic arrays. Current photovoltaic practice uses glass or other clear polymeric sheets that are smooth or textured uniformly. This makes residential rooftop modules and arrays readily noticeable.

It has been found that by patterning the upper or first sheet of a photovoltaic module using, for example a substantially textured pattern to mimic the appearance of roofing shingles, helps to camouflage the photovoltaic modules and arrays so they are not as apparent on the roof top of a house or other structure. Such patterning or texturing the first sheet improves the aesthetics of such roof mounted photovoltaic modules. By using glass or clear polymeric material which has been textured into rectangular (or other appropriately shaped) patches with different degrees or patterns of texturing, the array or module can appear like roofing shingles, which would make their appearance aesthetically pleasing.

### SUMMARY OF THE INVENTION

This invention is directed to a photovoltaic module. The module has a first sheet of a transparent material with at least a first surface and a second surface, and an optional second sheet. There is at least one photovoltaic cell positioned between the first sheet and the optional second sheet. The transparent material may be made of glass or a clear polymeric material, and has a camouflaged pattern. The camouflaged pattern may also include a substantially textured pattern.

This invention is also directed to a method for making a photovoltaic module comprising sealing at least one photovoltaic cell between a first sheet and a second sheet, wherein the first sheet comprises a camouflaged pattern.

### BRIEF DESCRIPTION OF THE FIGURES

FIG. 1 is drawing of one embodiment of the photovoltaic module of this invention.

FIG. 2 is a drawing of the underside of the photovoltaic module shown in FIG. 1.

FIG. 3 is a drawing of one embodiment of a first sheet having a camouflaged pattern.

### DETAILED DESCRIPTION OF THE INVENTION

This invention is directed to a photovoltaic module comprising a first sheet, an optional second sheet comprising, for example, a polyester material, a photovoltaic cell or a plurality of photovoltaic cells embedded in an encapsulant, where each photovoltaic cell is positioned between the first sheet and the second sheet.

The first sheet can be made of any suitable material that is transparent to solar radiation, particularly to solar radiation in the visible range. The first sheet is preferably a flat sheet with at least a first surface and a second surface. For example, the first sheet can be made of glass or a polymeric material. Preferably, it is made of clear, tempered or heat strengthened glass. The first sheet can be of any convenient size and thickness. For example, it can be about 1 to about 20 square feet and can, for example, be rectangular or square in shape. The thickness of the first sheet is variable and will, in general, be selected in view of the application of the module. If, for example, the module uses glass as the first sheet, the glass can range in thickness from about 3.2 mm to about 5 mm.

The first sheet has a camouflaged pattern, either within the first sheet, on one of its surfaces, or a combination thereof. As used herein, a “camouflaged pattern” means a pattern that at least partially assimilates the appearance of the photovoltaic module to the appearance of the roof or other structure upon or over which the photovoltaic module is mounted. A camouflaged pattern thus reduces the “stand out” appearance of photovoltaic modules when mounted on a structure such as a roof and thereby increases the aesthetic appearance of the photovoltaic module, and especially, arrays made with such photovoltaic modules. For example, such camouflaged pattern can be a substantially textured pattern. As used herein, “substantially textured pattern” means any compilation of one or more types of irregularities such as, for example, marks, pits, cuts, striations, fractures, stippling, or other irregularities that are imparted, embossed, affixed, etched, imprinted, or otherwise applied or formed onto one or more of a surface, or the interior of first sheet, either in a random and/or ordered manner. The substantially textured pattern can mimic the appearance of roofing shingles, can break up the appearance of large surfaces into smaller surfaces, and can otherwise be used for roofing applications and on building facades.

Methods to make patterned glass are varied and well known in the art. Generally, patterned glass begins as a batch of materials, including silica sand, soda, and lime. These materials are melted together in a tank, and then the molten glass mixture is fed onto a machine slab. The molten glass then moves between counter-rotating rollers. One of these rollers is embossed, imprinting a distinctive pattern onto the soft surface of the glass. The other roller is smooth. The resulting glass is patterned and textured on one side, while smooth on the other side. Alternatively, the glass may have the textured surface sandwiched in between two smooth surfaces. The distance between the two rollers determines the ultimate thickness of the glass. Examples of methods for making patterned glass include U.S. Pat. Nos. 6,796,142, 6,372,327, 5,721,013, 5,460,638, 3,911,4118, and 3,841,857, all of which are incorporated herein by reference in their entirety.

The photovoltaic cells used in the photovoltaic modules of this invention can be any suitable photovoltaic cell. For example, they can be cells made from monocrystalline or polycrystalline (multicrystalline) silicon wafers, or wafers made from other suitable semiconductor materials. They can be thin film photovoltaic cells such as, for example, cells made from amorphous silicon or from cadmium telluride and cadmium sulfide. Methods for manufacturing photovoltaic cells are well-known in the art.

In the modules of this invention, the preferred photovoltaic cells are made from monocrystalline or multicrystalline wafers. These cells can be any shape, but are typically circular, square, rectangular or pseudo-square in shape. The term “pseudo-square” means a predominantly square shape usually with rounded corners. Also, a plurality of photovoltaic cells made from silicon monocrystalline or multicrystalline wafers may be connected in series or other desirable arrangement using suitable electrical conduits such as wires or electrically conducting metal strips. The individual photovoltaic cells are arranged and electrically connected to achieve a desired output voltage of the module when the module is exposed to the sun.

The optional second sheet (or back sheet) for the photovoltaic module of this invention can comprise a polyester material. Specific polyesters are polyethylene terephthalate (also known as PET), polybutylene terephthalate (also known as PBT) and polyethylene naphthalate (also known as PEN). Polyesters can be made from mixtures of polycarboxylic acids and from mixtures of polyols. The polyester material can also be a blend of one or more different polyesters. The polyester material can also contain additives blended therein such as one or more of a colorant or pigment, plasticizer, flame retardant, filler, antioxidant, ultraviolet (UV) stabilizer, or other additive. Optionally, the back sheet may also comprise polyvinyl fluoride (PVF) products such as DuPont™ Tedlar®, and metals including stainless steel and aluminum. Preferably, the back sheet in the photovoltaic module of this invention is a polyester material.

In a typical procedure for constructing a module in accordance with this invention, the electrically connected photovoltaic cells are positioned adjacent to or on the first sheet, having the camouflaged pattern described above, or attached to it using an encapsulant such as a sheet of ethylene vinyl acetate (EVA) or other suitable encapsulant, and an encapsulant material such as a sheet of ethylene vinyl acetate (EVA) or other suitable encapsulant is positioned between the photovoltaic cells and a back sheet. The first sheet, photovoltaic cells and second sheet are then pressed together, i.e., laminated, to form a unit sealed by the encapsulant material and comprising a first sheet, a plurality of electrically connected cells and a second sheet. The lamination process is typically conducted at an elevated temperature and under reduced pressure. The temperature for such lamination should be a temperature that is about or higher than the cure temperature of the encapsulant used to seal the first sheet to the second sheet. For example, when the encapsulant is a sheet of EVA, this temperature should be at least about 130° C. The use of a reduced pressure during the lamination process reduces or eliminates the formation of unwanted bubbles in the laminate. In order to improve the adhesion of the encapsulant, such as a sheet of EVA, a primer material can be added to the surfaces of the second sheet, incorporated in the encapsulant, or both. Such primers are for example organo-reactive silanes such as Dow Corning Z6020, Z6030, Z6040, Z6076 or Z6094.

The second sheet can have openings through which pass electrical connectors, such as insulated wires or electrical cables, that connect to the photovoltaic cells within the laminated module. When the module is in operation these output cables are used to connect the module to the system or device that will utilize the electrical current generated by the module. The openings in the back sheet through which such output cables pass can be, and preferably are, covered by a junction box. The junction box is suitably made of an electrically non-conducting polymeric material. Preferably the junction box is attached to the back sheet on the underside of the module using an adhesive, and the junction box is typically filled with a sealant so that moisture is prevented from entering the laminate through the openings in the back sheet for the output cables. The junction box filled with sealant also serves to anchor the output cables so that they can be manipulated without causing damage to the finished module when the finished module is mounted for its intended application.

The invention will now be described with reference to the figures, which show certain embodiments of the invention, but are not meant in any way to limit the scope of the invention.

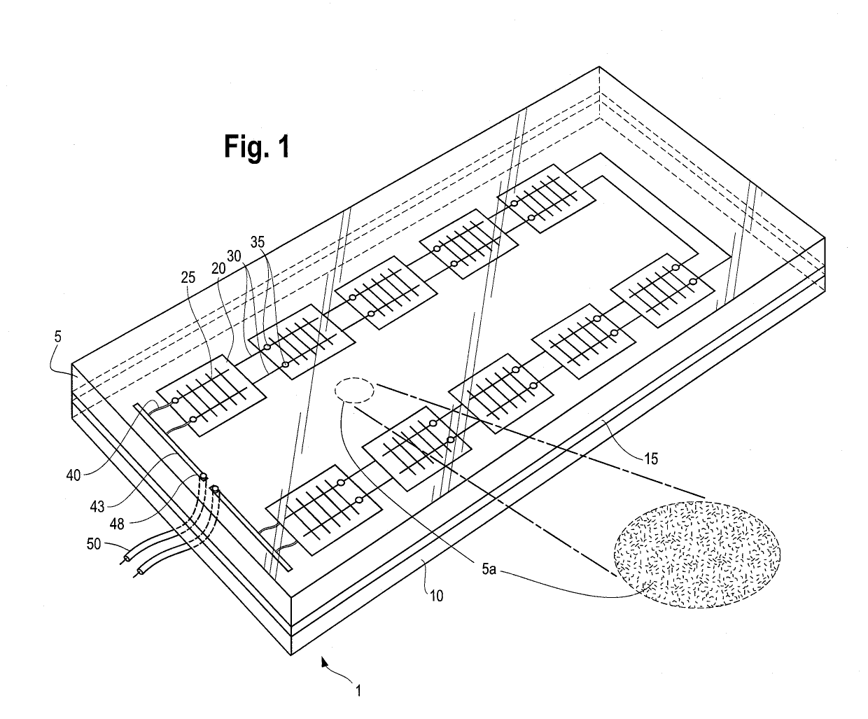

FIG. 1 shows one embodiment of the photovoltaic module of this invention. The photovoltaic module 1 in FIG. 1 has a first sheet 5, preferably made of glass or other suitable transparent material, and polyester second sheet 10. In FIG. 1, a small portion of first sheet 5, shown as 5a, displays a small portion of the sheet's substantially textured pattern. It is understood that the substantially textured pattern in 5a is representative of the entire first sheet 5, but for the clarity of FIG. 1, just a portion of first sheet 5 is shown as having this substantially textured pattern. The pattern shown is only one example of a substantially textured pattern. Other patterns, such as one or more of those described herein, can also be used. Between first sheet 5 and second sheet 10 is sandwiched a plurality of photovoltaic cells 20 electrically connected in series, a shown in FIG. 1. Between the first sheet 5 and the second sheet 10 is a sheet of ethylene vinyl acetate (EVA) 15 that seals the first sheet 5 to the second sheet 10 with the photovoltaic cells 20 sealed in between. For clarity, in FIG. 1, only one photovoltaic cell is designated by a number 20. These photovoltaic cells can be any type of photovoltaic cell such as cells made from multicrystalline or monocrystalline silicon wafers. Each cell, as shown in the FIG. 1, has a grid-type, front electrical contact 25. (For clarity, only one grid-type front contact is labeled in the figure.) Sunlight enters through first sheet 5 and impinges on the front side of the photovoltaic cells 20. Photovoltaic cells 20 are electrically connected in series by wires 30. Wires 30 are attached to the back contact on the back side of photovoltaic cells 20 (back side of photovoltaic cells not shown) and to solder contact points 35 on front side of photovoltaic cells 20 to form the series connected cells. (For clarity, only one set of wires 30 and one set of solder contact points 35 on front side of photovoltaic cells are labeled in FIG. 1.) The wires 30 are suitably flat, tinned-copper leads, electrical wires or other suitable electrical conduits.

The first and last photovoltaic cell in the series-connected cells shown in the module of FIG. 1 are connected by the electrical connection conduit 40 of the end cells to bus bars 45. Bus bars 45 are also electrical conduits, and can be, for example, wires or flat electrical leads. Bus bars 45 end with solder points 48. Electrical cables 50 are soldered to bus bars 45 at solder points 48. Electrical cables extend out the underside of module 1 through holes in back sheet 10 (not shown in FIG. 1). Electrical cables 50 are used to electrically connect module 1 to the system or device that will use the electrical current generated by photovoltaic module 1. (For clarity only one electrical conduit 40, one bus bar 45, one solder point 48 and one cable 50 are labeled in FIG. 1.)

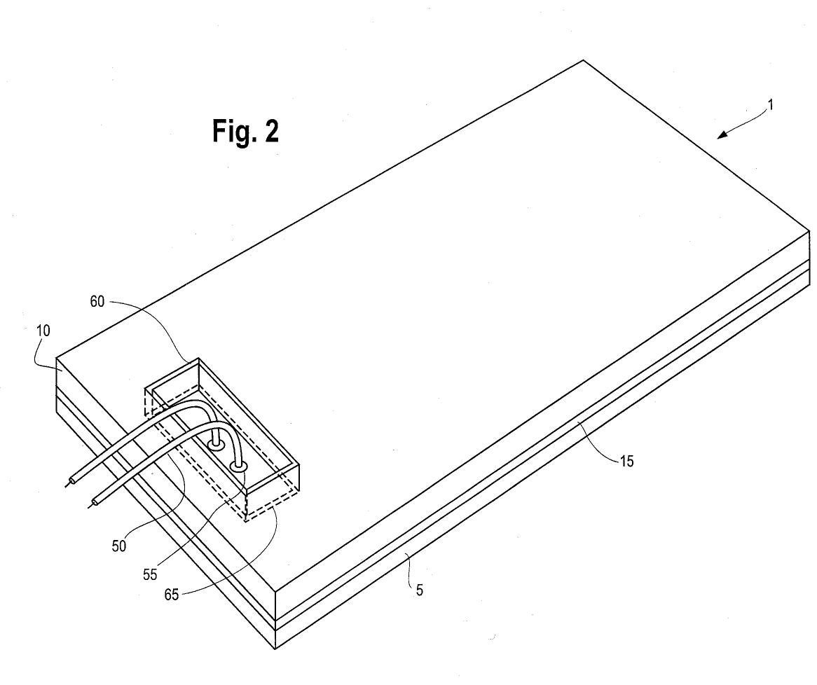

FIG. 2 shows the underside of the photovoltaic module shown in FIG. 1. In FIG. 2, the elements that are the same as in FIG. 1 are numbered the same. FIG. 2 shows electrical cables 50 extending from openings 55 in back sheet 10. Around openings 55 is junction box 65. Junction box 65 is, for clarity, shown without a cover. In its finished form, junction box 60 would have a cover and cables 50 would extend through openings in such cover or through one or more of the sides of the junction box. Junction box 60 would also be filled with a suitable sealant such as a silicone or an epoxy. The sealant in the junction box seals the openings 55 and also serves to anchor cables 50 so that they do not disrupt the seal around opening 55 when the cables are manipulated. Bottom surface 65 of junction box 60 is preferably attached to back (second) sheet 10 using an adhesive. We determined that adhesives having a neutral rather than an acidic curing system are preferred for adhering a junction box to a back sheet comprising a polyester material. For example, we discovered that adhesives having an alkoxy-, amine-, enoxy- or oxime-type cure system form a moisture resistant lasting bond between the junction box and the polyester sheet. Oxime-cured adhesives such as Dow Corning 737 and enoxy-cured adhesives such as Shin Etsu KE347TUV are suitable. Amine-cured adhesives such as Dow Corning RTV 790 and alkoxy-cured adhesives such as Dow Corning RTV 739 are also suitable adhesives for adhering the junction box to the back sheet comprising a polyester material.

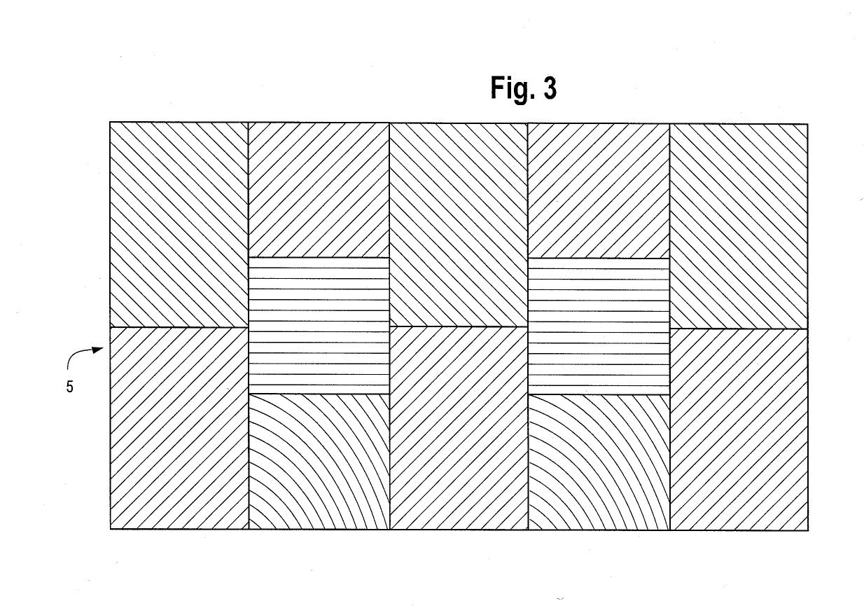

FIG. 3 is a drawing of one embodiment of first sheet 5 having a camouflaged pattern, which could be a substantially textured pattern. The pattern shown in FIG. 3 is only one example of a camouflaged pattern.

Although the invention has been described with respect to photovoltaic modules containing photovoltaic cells made from silicon wafers, it is to be understood, as mentioned above, that the invention is not limited to such photovoltaic cells. The photovoltaic cells can be of any type. For example, they can be thin film-type photovoltaic cells such as thin film amorphous silicon cells or CdS/CdTe cells. Such photovoltaic cells are known in the art and can be deposited onto a suitable superstrate material such as glass or metal by known methods. For example, methods for forming amorphous silicon cells which can be used in this invention are set forth in U.S. Pat. Nos. 4,064,521 and 4,292,092, UK Patent Application 9916531.8 (Publication No. 2339963, Feb. 9, 2000) all of which are incorporated herein by reference in their entirety.

This invention is also directed to a method for making a photovoltaic module, comprising sealing at least one photovoltaic cell between a first sheet and a second sheet, wherein the first sheet comprises a substantially textured pattern

It is to be understood that only certain embodiments of the invention have been described and set forth herein. Alternative embodiments and various modifications will be apparent from the above description to those of skill in the art. These and other alternatives are considered equivalents and within the spirit and scope of the invention.

What is claimed is:

1. A photovoltaic module comprising a first sheet of a transparent material comprising at least a first surface and a second surface, an optional second sheet, and at least one photovoltaic cell positioned between said first sheet and said optional second sheet, and wherein said transparent material comprises a camouflaged pattern.

2. The photovoltaic module of claim 1, wherein said transparent material comprises glass.

3. The photovoltaic module of claim 1, wherein said transparent material comprises a clear polymeric material.

4. The photovoltaic module of claim 1, wherein said camouflaged pattern comprises a substantially textured pattern.

5. The photovoltaic module of claim 4, wherein said substantially textured pattern mimics the appearance of roofing shingles.

6. The photovoltaic module of claim 1, wherein said camouflaged pattern is on at least one surface.

7. The photovoltaic module of claim 1, wherein said camouflaged pattern is within said first sheet.

8. The photovoltaic module of claim 1, wherein said second sheet comprises a polyester material.

9. The photovoltaic module of claim 1, wherein said second sheet comprises stainless steel.

10. The photovoltaic module of claim 1, wherein said second sheet comprises aluminum.

11. The photovoltaic module of claim 1 further comprising an encapsulant.

12. The photovoltaic module of claim 11 wherein said encapsulant seals the first sheet to the second sheet.

13. The photovoltaic module of claim 1 comprising a second sheet and a junction box attached to said second sheet.

14. A method for making a photovoltaic module comprising sealing at least one photovoltaic cell between a first sheet and a second sheet, wherein the first sheet comprises a camouflaged pattern.
